(19) United States
(12) Patent Application Publication
(10) Pub. No.: US 2022/0416503 A1
(43) Pub. Date: Dec. 29, 2022

(54) MULTIPLE METAL LAYERS WITHIN A PHOTONICS INTEGRATED CIRCUIT FOR THERMAL TRANSFER

(71) Applicant: Intel Corporation, Santa Clara, CA (US)

(72) Inventors: Priyanka DOBRIYAL, Milpitas, CA (US); Aditi MALLIK, Cupertino, CA (US); Saeed FATHOLOLOUMI, Los Gatos, CA (US); Ankur AGRAWAL, Chandler, AZ (US); Anna PRAKASH, Chandler, AZ (US); Hemant Mahesh SHAH, Hillsboro, OR (US); Raiyomand ASPANDIAR, Portland, OR (US); Neil Raymund CARANTO, Santa Clara, CA (US)

(21) Appl. No.: 17/357,938

(22) Filed: Jun. 24, 2021

(51) Int. Cl. H01S 5/024; H01S 5/34

(52) U.S. Cl. CPC H01S 5/02476; H01S 5/34; H01S 5/02469

(57) ABSTRACT

Embodiments described herein may be related to apparatuses, processes, and techniques related to thermal routing techniques within a hybrid silicon laser or photonics integrated circuit to facilitate heat extraction during laser operation. In particular dual metal layers, with a top metal layer thermally coupled with P node above a quantum well and extending substantially under a heat sink, and a bottom metal layer thermally coupled with an N node, where the top metal layer and the bottom metal layer are not electrically coupled. Other embodiments may be described and/or claimed.

### FIELD

Embodiments of the present disclosure generally relate to the field of semiconductor packaging, and in particular to photonics integrated circuits (PIC) within a package.

### BACKGROUND

Continued growth in computing and mobile devices will continue to increase the demand for increased bandwidth density between dies within semiconductor packages.

### BRIEF DESCRIPTION OF THE DRAWINGS

FIG. 1 illustrates a top view and a side view of a legacy photonics integrated circuit (PIC) having laser regions coupled with a heat sink die (HSD).

FIG. 2 illustrates a side view of a first and second metal layer within a PIC, in accordance with various embodiments.

FIG. 3 illustrates a top view of a laser under an HSD with multiple conductivity features, in accordance with various embodiments.

FIGS. 4A-4P stages in a manufacturing process depositing carbon nanotubes (CNT) on the planar surface of the silicon die, in accordance with various embodiments.

FIG. 5 illustrates a top view and a side view of a PIC that includes CNT acting as a thermal interface material (TIM) coupled with an HSD, in accordance with various embodiments.

FIG. 6 illustrates a top view and a side view of a legacy implementation of copper pillars thermally coupling with an HSD.

FIG. 7 illustrates a top view and a side view of a PIC that includes the 3 μm aluminum layer that is coupled with an HSD, in accordance with various embodiments.

FIG. 8 illustrates a top view and side view of a PIC that includes CNT on top of a 3 μm metal layer thermally coupled with an HSD, in accordance with various embodiments.

FIG. 9 illustrates an example of a process for creating a portion of a PIC that has two metal layers for thermal management of a laser portion of the PIC, in accordance with various embodiments.

FIG. 10 schematically illustrates a computing device, in accordance with various embodiments.

### DETAILED DESCRIPTION

Embodiments described herein may be related to apparatuses, processes, and techniques related to thermal routing techniques within a hybrid silicon laser or a PIC to facilitate heat extraction during operation. In particular, embodiments include dual metal layers, with a top metal layer thermally coupled with P node above a quantum well and extending substantially under a HSD, and a bottom metal layer thermally coupled with an N node, where the top metal layer and the bottom metal layer are not electrically coupled. In embodiments, carbon nanotubes (CNT) may be placed on the top metal layer to further facilitate thermal conductivity away from the laser.

Legacy implementations of PICs have little to no thermal margin around the laser area. In particular, legacy implementations may include some copper pillars proximate to the hybrid silicon laser area. However, the copper pillars are kept away from the immediate area of the laser due to the high risk of copper bump-induced thermomechanical stress as well as metal migration. As a result, the lack of copper pillars in the immediate area of the laser allows higher laser junction temperatures. These higher laser junction temperatures may result in product reliability issues during operation. In embodiments described herein, references to a laser or laser devices may also refer to any active photonic device (APD).

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

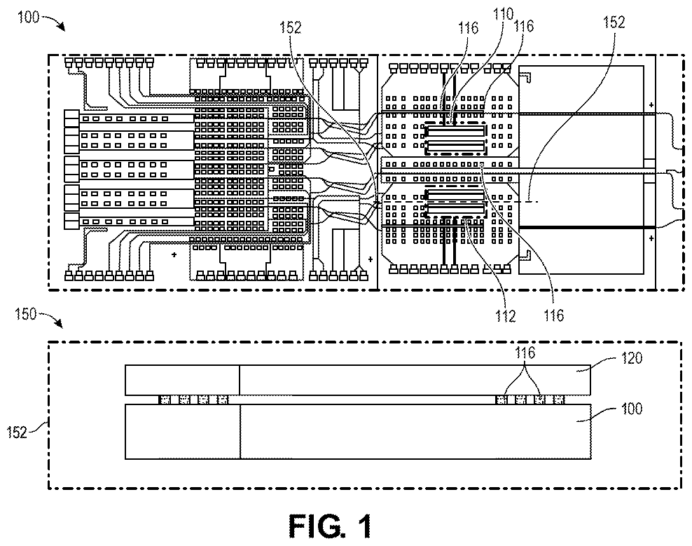

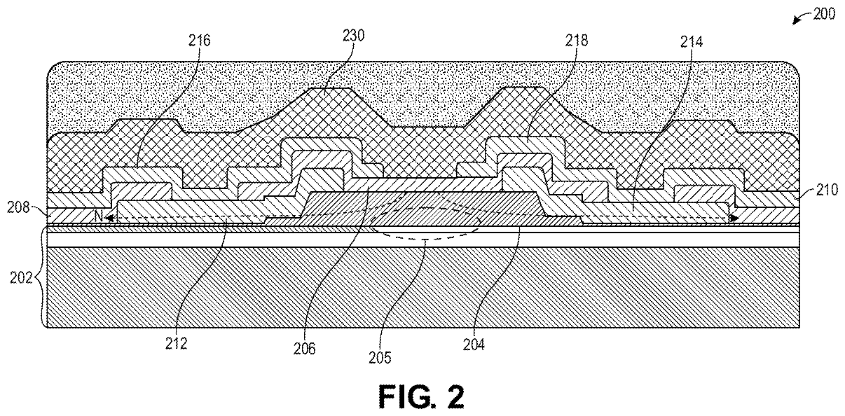

FIG. 1 illustrates a top view and a side view of a legacy PIC having laser regions coupled with a HSD. FIG. 1 shows a PIC top down view 100 and a PIC/HSD side view 150 at a cut area 152. Laser regions 110, 112 include one or more laser elements, that may be similar to laser elements is shown with respect to FIG. 2 below. Copper pillars 116 thermally couple the PIC 100 with the HSD 120. The copper pillars 116 may have a height of 60 μm, and may include a solder (not shown) when they are thermally coupled with the HSD 120. However, within the laser regions 110, 112 there are no copper pillars in this legacy implementation. This is because copper pillars placed too close to the laser area can cause laser degradation due to thermal mechanical stress and/or metal electro migration from copper pillars which can damage lasers. The lack of copper pillars 116 within the laser regions 110, 112 result in very tight thermal margins for the lasers during operation.

FIG. 2 illustrates a side view of a first and second metal layer within a PIC, in accordance with various embodiments. PIC 200 includes a substrate 202, onto which a quantum well 204 is placed. In embodiments, the substrate 202 may be a silicon on insulator (SOI) wafer that may result in heat generated within a hotspot 205 to be blocked by a buried oxide (BOX) layer at the bottom of the substrate 202 and a oxide cladding layer on the top of substrate 202.

In embodiments, the quantum well 204 may include indium phosphide (InP) or a direct-band-gap material. A P node 206 may be placed on top of the quantum well 204, and in embodiments may be a layer above the quantum well 204. N nodes 208, 210 may be placed at the sides of the quantum well 204, and may be located, respectively, within separate first metal layers. In embodiments, dielectric layers 212, 214 may separate, respectively, the N nodes 208, 210 from a portion of the quantum well 204.

A second metal layer 230 may be coupled with a top portion of the P node 206 and may extend substantially across the PIC 200. In embodiments, the second metal layer 230 may extend above the respective N nodes 208, 210. During operation of the laser, heat from the laser hot spot, generated primarily in circled area 205 near the center of the quantum well 204, may be efficiently conducted through the P node 206 and into the second metal layer 230. Heat within the second metal layer 230 may then be efficiently dispersed throughout the second metal layer 230, and may be routed outside of the PIC 200, as discussed further below.

In embodiments, the first metal layers that include the N nodes 208, 210 are not electrically coupled with the second metal layer 230. In embodiments, the first metal layers that include the N nodes 208, 210 are separated by one or more dielectric layers, such as dielectric layer 212, 214, as well as by dielectric layers 216, 218. In embodiments, the layers that include the N nodes 208, 210 may be routed under the second metal layer 230. In embodiments, the second metal layer 230 may have a thickness within a range of 3 μm to 8 μm.

By directly thermally coupling the second metal layer 230 with the P node 206, the second metal layer 230 is able to effectively extract thermal energy from an otherwise low thermally conductive quantum well 204 that would trap heat at the laser core, near area 205. In embodiments, the second metal layer 230 may extend over and thermally couple with multiple P nodes (not shown, but maybe similar to the P nodes in laser regions 110, 112 of FIG. 1).

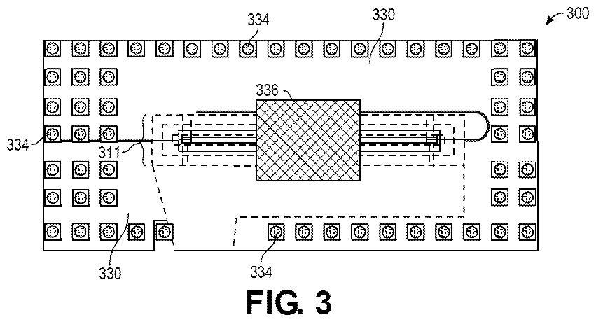

FIG. 3 illustrates a top view of a laser under an HSD with multiple conductivity features, in accordance with various embodiments. PIC 300 shows a top-down view of a PIC that may be similar to PIC 200 of FIG. 2. A second metal layer 330, that may be similar to second metal layer 230 of FIG. 2, covers and is thermally coupled with a laser region 311, that may include elements similar to quantum well 204, P node 206, and N nodes 208, 210 of FIG. 2.

A plurality of copper bumps 334 may be thermally and/or physically coupled to the second metal layer 330. In embodiments, the plurality of copper bumps 334 may be coupled with an HSD, that may be similar to HSD 120 of FIG. 1. In embodiments, region that includes a nanotube layer 336 may be placed on the second metal layer 330 to provide additional thermal conductivity to route heat away from the second metal layer 330. Although the nanotube layer 336 is shown above the laser region 311, the nanotube layer 336 may be placed anywhere on the second metal layer 330. A process for depositing the nanotube layer 336 is described further below.

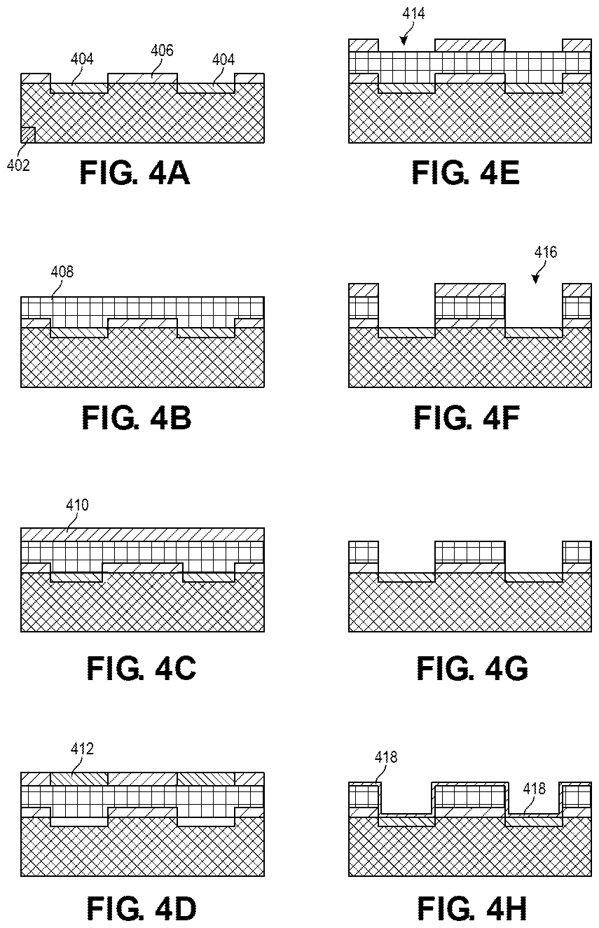

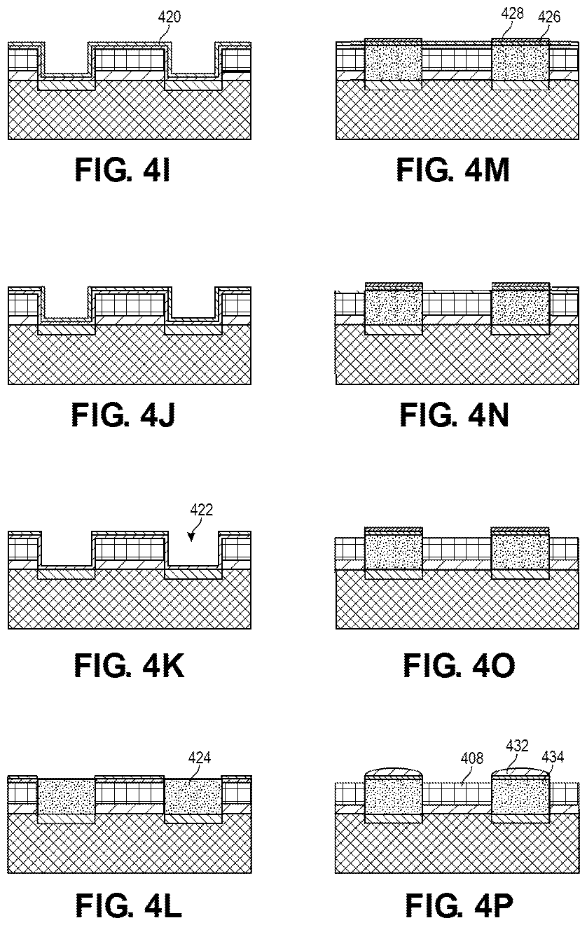

FIGS. 4A-4P stages in a manufacturing process depositing carbon nanotubes (CNT) on the planar surface of the silicon die, in accordance with various embodiments. In embodiments, layers of the nanotubes may provide efficient thermal conductivity that may be used to conduct heat from a metal layer through to a heatsink, or to some other thermal routing path.

FIG. 4A shows an incoming wafer that includes a silicon wafer 402 with a plurality of aluminum (Al) pads 404, with a passivation layer 406 on top of the silicon wafer 402.

FIG. 4B shows the result of a spin coat of CNT 408 applied to the top of the incoming wafer.

FIG. 4C shows a pattern resist layer 410 applied to the top of the CNT coating 408.

FIG. 4D shows the result of exposing a pattern resist layer 412. In embodiments, the resist layer 412 is exposed to match the bump passivation opening which will be exposed in the subsequent photoresist development of FIG. 4E and CNT at etch of FIG. 4F. After that, bump plating can continue.

FIG. 4E shows the result of the developed pattern resist layer to create openings 414.

FIG. 4F shows result of an etching of the CNT layer to expose the AL pads 404, to form cavities 416.

FIG. 4G shows the result of removing the pattern resist layer 410.

FIG. 4H shows the result of sputter depositing a Ti/Cu seed layer 418.

FIG. 4I shows the result of applying a plating resist layer 420.

FIG. 4J shows the result of exposing the plating resist layer 420.

FIG. 4K shows the result of developing the plating resist layer to create cavities 422 that have the seed layer 418 at the bottom.

FIG. 4L shows the result of plating copper pillars 424 within the cavities 422.

FIG. 4M shows the result of plating a nickel barrier layer 426 and plating a SnAg solder layer 428 on the copper pillars 424.

FIG. 4N shows the result of removing the photoresist layer 420.

FIG. 4O shows a result of etching away the seed layer 418.

FIG. 4P shows a result of reflowing SnAg solder 432. Thus, FIG. 4P shows coated copper pillars 434, which may be similar to copper bumps 334 of FIG. 3, as well as CNT coating 408 which may be similar to the CNT region 336 of FIG. 3. Table 1 below compares key CNT material properties versus other materials.

TABLE 1

| | Thermal | | Alignment/ | Isotropic | Deposition |
|---|---|---|---|---|---|
| Material | Properties | | Orientation | Properties | Methods |
| Carbon | 700 | W/m · K | Yes | Yes | Spin coat |
| Nanotubes | | | | | |
| Carbon | 1056 | W/m · K | No | No | CVD + |
| Nano- | | | | | spin coat |
| tubes + | | | | | |
| Graphene | | | | | |
| hybrid | | | | | |
| Graphene | 1434 | W/m · K | Yes/ | Yes | Electro |
| | | | Difficult | | spray |
| | | | | | deposition |
| Solder | 87 | W/m · K | No | No | Embedded |
| TIM | | | | | within |
| | | | | | HSD lid |
| Thermal | 3-12 | W/m · K | No | No | Manual |
| grease | | | | | dispense |

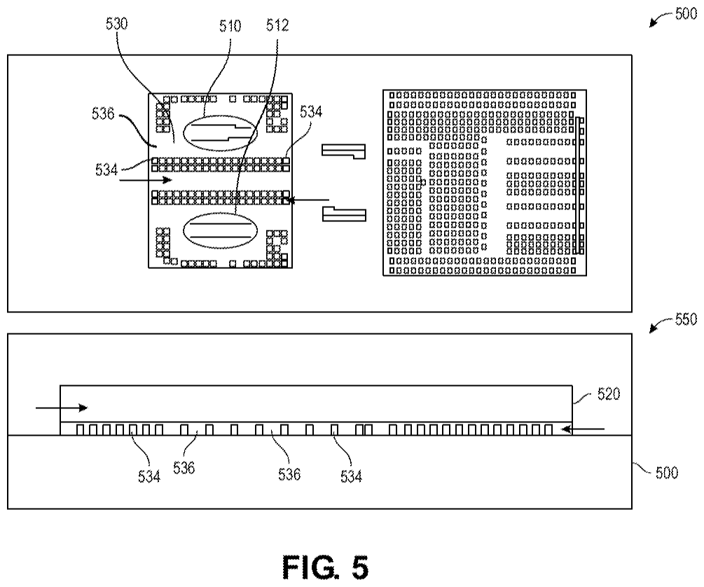

FIG. 5 illustrates a top view and a side view of a PIC that includes CNT acting as a TIM coupled with an HSD, in accordance with various embodiments. PIC top-down view 500, shows a plurality of laser regions 510, 512 that are below a second metal layer 530, which may be similar to second metal layer 230 of FIG. 2, over the laser regions 510, 512. A plurality of copper bumps 534 are placed on the second metal layer 530, with CNT layer 536 interspersed between the copper bumps 534 on the second metal layer 530. PIC side view 550 shows the PIC 500 and an HSD 520, which may be similar to HSD 120 of FIG. 1, that is thermally coupled with the copper bumps 534 and the CNT layer 536.

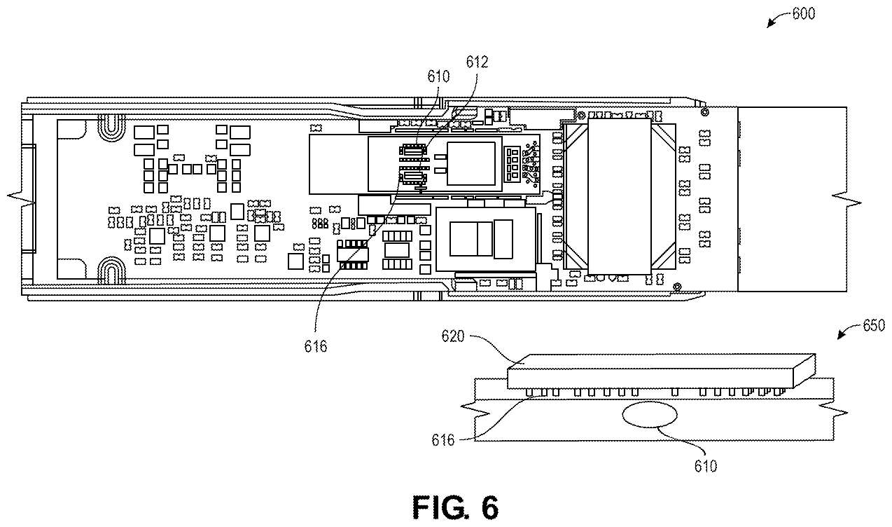

FIG. 6 illustrates a top view and a side view of a legacy implementation of copper pillars thermally coupling with an HSD. PIC top-down view 600 shows laser regions 610, 612, with copper pillars 616 placed around the laser regions 610, 612, but not within the actual laser regions 610, 612. The legacy copper pillars 616 are coupled with a HSD 620 to provide the thermal routing to the HSD 620 from the pick 616. PIC side view 650 shows a cross-section of the PIC 600 along with a HSD 620. As shown, the lack of thermal conductive elements, such as copper bumps or CNT, proximate to the laser regions 610, 612, will result in reduced thermal cooling and increased thermal margins as compared to embodiments described herein.

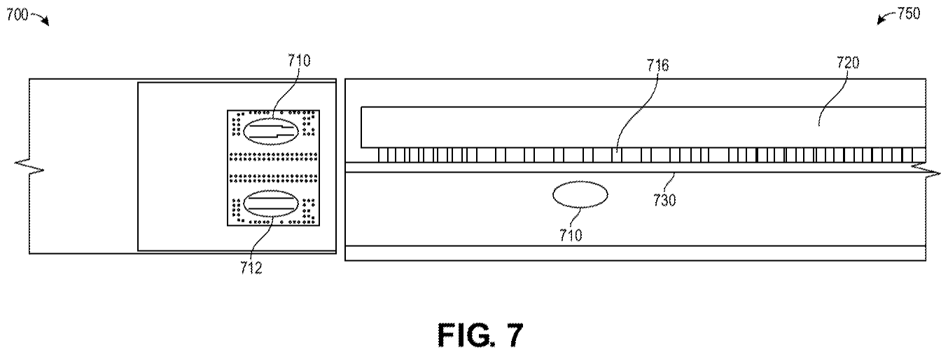

FIG. 7 illustrates a top view and a side view of a PIC that includes the 3 μm aluminum layer that is coupled with an HSD, in accordance with various embodiments. PIC top view 700 shows laser regions 710, 712 that are covered with a second metal layer 730, similar to second metal layer 530 of FIG. 5. As shown, the second metal layer 730 may be an aluminum layer. In embodiments, the aluminum second metal layer 730 may range from 2 μm to 4 μm.

PIC cross-section 750 shows the second metal layer 730, that is thermally coupled with HSD 720, which may be similar to HSD 520 of FIG. 5. Note that the plurality of copper bumps 716 provide the thermal coupling, and the bumps 716 are included above the laser regions 710, 712.

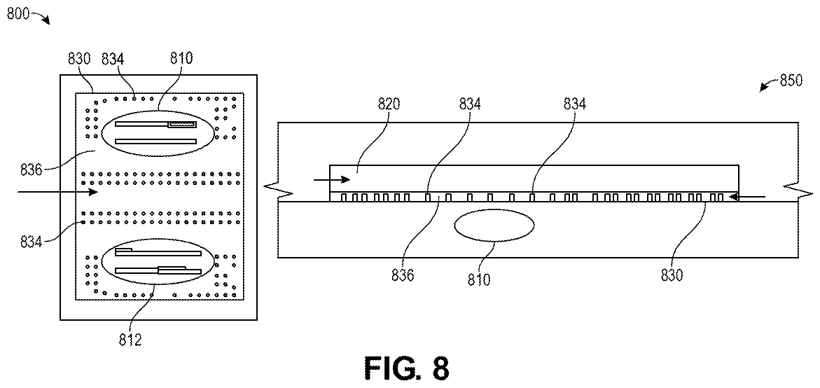

FIG. 8 illustrates a top view and side view of a PIC that includes CNT on top of a 3 μm metal layer thermally coupled with an HSD, in accordance with various embodiments. PIC top view 800 shows laser regions 810, 812, which may be similar to laser regions 710, 712 of FIG. 7. A second metal layer 830, which may be similar to second metal layer 730 of FIG. 7, is thermally coupled with the laser portions 810, 812. A plurality of copper bumps 834 are placed above and around the laser regions 810, 812 on a top of the second metal layer 830. A CNT layer 836 also placed on a top of the second metal layer 830, interspersed with the copper bumps 834.

PIC side view 850 shows an HSD 820, which may be similar to HSD 720 of FIG. 7, that is thermally coupled with the second metal layer 830. The thermal coupling is accomplished using a plurality of copper bumps 834, as well as the CNT layer 836 interspersed between the second metal layer 830 and the HSD 820.

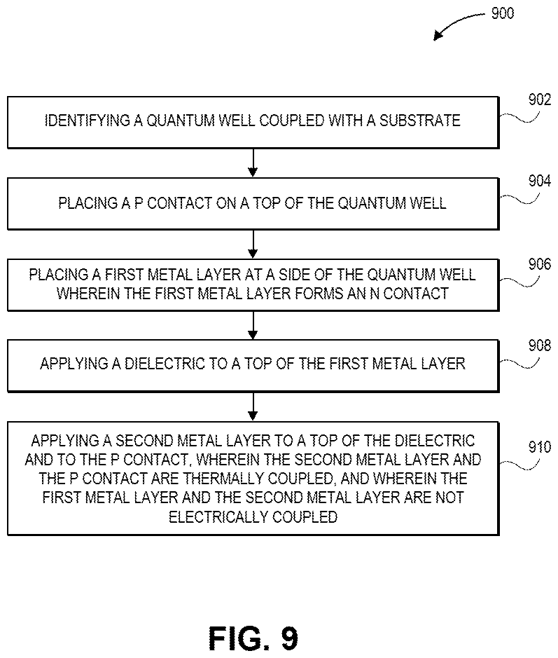

FIG. 9 illustrates an example of a process for creating a portion of a PIC that has two metal layers for thermal management of a laser portion of the PIC, in accordance with various embodiments. Process 900 may be implemented by one or more techniques described herein, in particular with respect to FIGS. 1-8.

At block 902, the process may include identifying a quantum well coupled with a substrate. In embodiments, the quantum well may be similar to quantum well 204, and the substrate may be similar to substrate 202 of FIG. 2.

At block 904, the process may further include placing a P contact on a top of the quantum well. In embodiments, the P contact may be similar to P contact 206 of FIG. 2.

At block 906, the process may further include placing a first metal layer at a side of the quantum well wherein the first metal layer forms an N contact. In embodiments, the first metal layer may be similar to the metal layer that includes the N node 208, or the first metal layer may be similar to the metal layer that includes the N node 210 of FIG. 2.

At block 908, the process may further include applying a dielectric to a top of the first metal layer. In embodiments, the dielectric may be similar to dielectric layer 216, or maybe similar to dielectric 218 of FIG. 2.

At block 910, the process may further include applying a second metal layer to a top of the dielectric and to the P contact, wherein the second metal layer and the P contact are thermally coupled, and wherein the first metal layer and the second metal layer are not electrically coupled. In embodiments, the second metal layer may be similar to second metal layer 230 of FIG. 2.

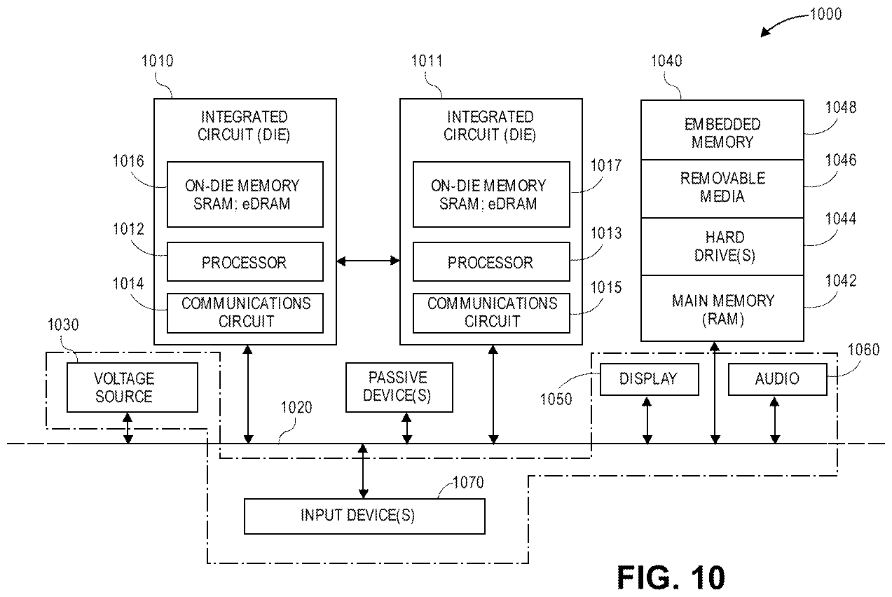

FIG. 10 schematically illustrates a computing device, in accordance with various embodiments. FIG. is a schematic of a computer system 1000, in accordance with an embodiment of the present invention. The computer system 1000 (also referred to as the electronic system 1000) as depicted can embody multiple metal layers within a PIC for thermal transfer, according to any of the several disclosed embodiments and their equivalents as set forth in this disclosure. The computer system 1000 may be a mobile device such as a netbook computer. The computer system 1000 may be a mobile device such as a wireless smart phone. The computer system 1000 may be a desktop computer. The computer system 1000 may be a hand-held reader. The computer system 1000 may be a server system. The computer system 1000 may be a supercomputer or high-performance computing system.

In an embodiment, the electronic system 1000 is a computer system that includes a system bus 1020 to electrically couple the various components of the electronic system 1000. The system bus 1020 is a single bus or any combination of busses according to various embodiments. The electronic system 1000 includes a voltage source 1030 that provides power to the integrated circuit 1010. In some embodiments, the voltage source 1030 supplies current to the integrated circuit 1010 through the system bus 1020.

The integrated circuit 1010 is electrically coupled to the system bus 1020 and includes any circuit, or combination of circuits according to an embodiment. In an embodiment, the integrated circuit 1010 includes a processor 1012 that can be of any type. As used herein, the processor 1012 may mean any type of circuit such as, but not limited to, a microprocessor, a microcontroller, a graphics processor, a digital signal processor, or another processor. In an embodiment, the processor 1012 includes, or is coupled with, multiple metal layers within a PIC for thermal transfer, as disclosed herein. In an embodiment, SRAM embodiments are found in memory caches of the processor. Other types of circuits that can be included in the integrated circuit 1010 are a custom circuit or an application-specific integrated circuit (ASIC), such as a communications circuit 1014 for use in wireless devices such as cellular telephones, smart phones, pagers, portable computers, two-way radios, and similar electronic systems, or a communications circuit for servers. In an embodiment, the integrated circuit 1010 includes on-die memory 1016 such as static random-access memory (SRAM). In an embodiment, the integrated circuit 1010 includes embedded on-die memory 1016 such as embedded dynamic random-access memory (eDRAM).

In an embodiment, the integrated circuit 1010 is complemented with a subsequent integrated circuit 1011. Useful embodiments include a dual processor 1013 and a dual communications circuit 1015 and dual on-die memory 1017 such as SRAM. In an embodiment, the dual integrated circuit 1010 includes embedded on-die memory 1017 such as eDRAM.

In an embodiment, the electronic system 1000 also includes an external memory 1040 that in turn may include one or more memory elements suitable to the particular application, such as a main memory 1042 in the form of RAM, one or more hard drives 1044, and/or one or more drives that handle removable media 1046, such as diskettes, compact disks (CDs), digital variable disks (DVDs), flash memory drives, and other removable media known in the art. The external memory 1040 may also be embedded memory 1048 such as the first die in a die stack, according to an embodiment.

In an embodiment, the electronic system 1000 also includes a display device 1050, an audio output 1060. In an embodiment, the electronic system 1000 includes an input device such as a controller 1070 that may be a keyboard, mouse, trackball, game controller, microphone, voice-recognition device, or any other input device that inputs information into the electronic system 1000. In an embodiment, an input device 1070 is a camera. In an embodiment, an input device 1070 is a digital sound recorder. In an embodiment, an input device 1070 is a camera and a digital sound recorder.

As shown herein, the integrated circuit 1010 can be implemented in a number of different embodiments, including multiple metal layers within a PIC for thermal transfer, according to any of the several disclosed embodiments and their equivalents, an electronic system, a computer system, one or more methods of fabricating an integrated circuit, and one or more methods of fabricating an electronic assembly that includes a package substrate having multiple metal layers within a PIC for thermal transfer, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having multiple metal layers within a hybrid silicon laser for thermal transfer embodiments and their equivalents. A foundation substrate may be included, as represented by the dashed line of FIG. 10. Passive devices may also be included, as is also depicted in FIG. 10.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### Examples

Example 1 is a photonic integrated circuit (PIC) apparatus comprising: a substrate; a quantum well coupled with the substrate; a P contact coupled with a top of the quantum well; an N contact coupled with a side of the quantum well, wherein the N contact is within a first metal layer; wherein the P contact is directly thermally coupled with a first side of a second metal layer, the second metal layer having a first side and a second side opposite the first side; wherein the first metal layer and the second metal layer are not electrically coupled; and wherein heat is transferred from the quantum well to the second metal layer via the P contact during operation of the PIC.

Example 2 includes the apparatus of example 1, wherein a dielectric layer electrically separates the first metal layer and the second metal layer.

Example 3 includes the apparatus of example 2, wherein the dielectric layer partially surrounds the P contact.

Example 4 includes the apparatus of example 2, wherein the dielectric layer is a first dielectric layer; and further comprising: a second dielectric layer that separates the top of the quantum well from the N contact.

Example 5 includes the apparatus of example 1, wherein the P contact is a first P contact; and further comprising: a second P contact coupled with the top of the quantum well; wherein the second P contact is directly thermally coupled with the first side of the second metal layer.

Example 6 includes the apparatus of example 1, wherein the first metal layer is between the second metal layer and the substrate.

Example 7 includes the apparatus of example 1, wherein an area of the second metal layer extends completely above the quantum well.

Example 8 includes the apparatus of example 1, further comprising a plurality of thermal transfer elements extending from the second side of the second metal layer, wherein heat is transferred from the second metal layer to the thermal transfer elements during operation of the PIC.

Example 9 includes the apparatus of example 8, wherein the plurality of thermal transfer elements include a selected one or more of: a copper bump, a copper pillar, or a carbon nanotube.

Example 10 includes the apparatus of example 8, wherein the plurality of thermal transfer elements are thermally coupled with a heat sink.

Example 11 includes the apparatus of example 10, wherein the heatsink is external to the PIC.

Example 12 includes the apparatus of any one of examples 1-11, wherein the second metal layer has a thickness of approximately 3 μm.

Example 13 includes the apparatus of any one of examples 1-11, wherein the substrate is a silicon on insulator substrate.

Example 14 is a method comprising: identifying a quantum well coupled with a substrate; placing a P contact on a top of the quantum well; placing a first metal layer at a side of the quantum well wherein the first metal layer forms an N contact; applying a dielectric to a top of the first metal layer; and applying a second metal layer to a top of the dielectric and to the P contact, wherein the second metal layer and the P contact are thermally coupled, and wherein the first metal layer and the second metal layer are not electrically coupled.

Example 15 includes the method of example 14, wherein the dielectric layer partially surrounds the P contact.

Example 16 includes a method of example 14, wherein the second metal layer extends completely above the quantum well.

Example 17 includes a method of example 14, further comprising: applying a plurality of thermal transfer elements the second metal layer.

Example 18 is a package comprising: a photonic integrated circuit (PIC) comprising: a substrate; a quantum well coupled with the substrate; a P contact coupled with a top of the quantum well; an N contact coupled with a side of the quantum well, wherein the N contact is within a first metal layer; wherein the P contact is directly thermally coupled with a first side of a second metal layer, the second metal layer having a first side and a second side opposite the first side; wherein the first metal layer and the second metal layer are not electrically coupled; and wherein heat is transferred from the quantum well to the second metal layer via the P contact during operation of the PIC; and a heatsink physically and thermally coupled with the second metal layer.

Example 19 includes the package of example 18, wherein the PIC further comprises a plurality of thermal transfer elements extending from the second side of the second metal layer to the heatsink, wherein heat is transferred from the second metal layer to the thermal transfer elements during operation of the PIC.

Example 20 includes the package of example 19, wherein at least some of the thermal transfer elements are located above the quantum well.

Example 21 includes the package of any one of examples 18-20, wherein the first metal layer and the second metal layer include copper.

What is claimed is:

1. A photonic integrated circuit (PIC) apparatus comprising:
a substrate;
a quantum well coupled with the substrate;
a P contact coupled with a top of the quantum well;
an N contact coupled with a side of the quantum well, wherein the N contact is within a first metal layer;
wherein the P contact is directly thermally coupled with a first side of a second metal layer, the second metal layer having a first side and a second side opposite the first side; and
wherein the first metal layer and the second metal layer are not electrically coupled.

2. The apparatus of claim 1, wherein heat is transferred from the quantum well to the second metal layer via the P contact during operation of the PIC.

3. The apparatus of claim 1, wherein a dielectric layer electrically separates the first metal layer and the second metal layer.

4. The apparatus of claim 3, wherein the dielectric layer partially surrounds the P contact.

5. The apparatus of claim 3, wherein the dielectric layer is a first dielectric layer; and further comprising:
a second dielectric layer that separates the top of the quantum well from the N contact.

6. The apparatus of claim 1, wherein the P contact is a first P contact; and further comprising:
a second P contact coupled with the top of the quantum well;
wherein the second P contact is directly thermally coupled with the first side of the second metal layer.

7. The apparatus of claim 1, wherein the first metal layer is between the second metal layer and the substrate.

8. The apparatus of claim 1, wherein an area of the second metal layer extends completely above the quantum well.

9. The apparatus of claim 1, further comprising a plurality of thermal transfer elements extending from the second side of the second metal layer, wherein heat is transferred from the second metal layer to the thermal transfer elements during operation of the PIC.

10. The apparatus of claim 9, wherein the plurality of thermal transfer elements include a selected one or more of: a copper bump, a copper pillar, or a carbon nanotube.

11. The apparatus of claim 9, wherein the plurality of thermal transfer elements are thermally coupled with a heat sink.

12. The apparatus of claim 11, wherein the heatsink is external to the PIC.

13. The apparatus of claim 1, wherein the second metal layer has a thickness of approximately 3 μm.

14. The apparatus of claim 1, wherein the substrate is a silicon on insulator substrate.

15. A method comprising:
identifying a quantum well coupled with a substrate;
placing a P contact on a top of the quantum well;
placing a first metal layer at a side of the quantum well wherein the first metal layer forms an N contact;
applying a dielectric to a top of the first metal layer; and
applying a second metal layer to a top of the dielectric and to the P contact, wherein the second metal layer and the P contact are thermally coupled, and wherein the first metal layer and the second metal layer are not electrically coupled.

16. The method of claim 15, wherein the dielectric layer partially surrounds the P contact.

17. The method of claim 15, wherein the second metal layer extends completely above the quantum well.

18. The method of claim 15, further comprising:
applying a plurality of thermal transfer elements the second metal layer.

19. A package comprising:
a photonic integrated circuit (PIC) comprising:
a substrate;
a quantum well coupled with the substrate;
a P contact coupled with a top of the quantum well;
an N contact coupled with a side of the quantum well, wherein the N contact is within a first metal layer;
wherein the P contact is directly thermally coupled with a first side of a second metal layer, the second metal layer having a first side and a second side opposite the first side;
wherein the first metal layer and the second metal layer are not electrically coupled; and
a heatsink physically and thermally coupled with the second metal layer.

20. The package of claim 19, wherein heat is transferred from the quantum well to the second metal layer via the P contact during operation of the PIC.

21. The package of claim 19, wherein the PIC further comprises a plurality of thermal transfer elements extending from the second side of the second metal layer to the heatsink, wherein heat is transferred from the second metal layer to the thermal transfer elements during operation of the PIC.

22. The package of claim 21, wherein at least some of the thermal transfer elements are located above the quantum well.
